(19) United States
(12) Patent Application Publication
(10) Pub. No.: US 2018/0087709 A1
(43) Pub. Date: Mar. 29, 2018

(54) SUBSTRATE PROCESSING APPARATUS AND HEAT INSULATING PIPE STRUCTURE

(71) Applicant: HITACHI KOKUSAI ELECTRIC INC., Tokyo (JP)

(72) Inventors: Mikio OHNO, Toyama-shi (JP); Akinori TANAKA, Toyama-shi (JP)

(73) Assignee: HITACHI KOKUSAI ELECTRIC INC., Tokyo (JP)

(21) Appl. No.: 15/706,028

(22) Filed: Sep. 15, 2017

(30) Foreign Application Priority Data
Sep. 28, 2016 (JP) 2016-189686

(51) Int. Cl. F16L 59/075; C23C 16/52; C23C 16/44; C23C 16/46

(52) U.S. Cl. CPC F16L 59/075; C23C 16/52; C23C 16/463; C23C 16/46; C23C 16/4412

(57) ABSTRACT

A configuration including a process chamber for processing a substrate, a gas supply system including supply pipe for supplying a source gas into the process chamber, and an exhaust system including exhaust pipe for discharging an exhaust gas containing the source gas from the process chamber, in which at least one of the supply pipe and the exhaust pipe includes an inner pipe constituting a first flow path of the source gas or the exhaust gas, a member provided outside the inner pipe and constituting a second flow path between the member and an outer wall of the inner pipe, and an outer pipe provided surrounding the inner pipe in order to provide a space between the outer pipe and an outside of the member.

### BACKGROUND

### Technical Field

The present invention relates to a substrate processing apparatus and a heat insulating pipe structure.

### Related Art

A semiconductor manufacturing apparatus requires supplying a required gas, exhausting the gas, and the like. The supply pipe and exhaust pipe of a gas includes a heater for heating the pipes. The heater is configured to prevent reliquefaction caused by cooling the gas or the like circulating inside the pipe and adhesion of by-products by maintaining a heated state. As a method for heating the pipe, directly winding a jacket heater having an electric heating wire buried in a heat insulating material and a glass cloth or the like around the pipe, or the like is known. In heating using the jacket heater, unevenness in a temperature of the pipe is generated disadvantageously due to variations in the degree of adhesion between a heater portion and the pipe.

### SUMMARY

The present teachings provides a configuration capable of suppressing adhesion of by-products to a cold spot due to uneven pipe temperatures.

According to one aspect of the present teachings, there is provided a configuration including a process chamber for processing a substrate, a gas supply system including supply pipe for supplying a source gas into the process chamber, and an exhaust system including exhaust pipe for discharging an exhaust gas containing the source gas from the process chamber, in which at least one of the supply pipe and the exhaust pipe includes an inner pipe constituting a first flow path of the source gas or the exhaust gas, a member provided outside the inner pipe and constituting a second flow path between the member and an outer wall of the inner pipe, and an outer pipe provided surrounding the inner pipe in order to provide a space between the outer pipe and an outside of the member.

According to one embodiment of the present teachings, temperature unevenness of pipe can be reduced.

### BRIEF DESCRIPTION OF DRAWINGS

FIG. 1 is a schematic vertical sectional view for explaining a process furnace suitably used in a substrate processing apparatus according to an embodiment;

FIG. 2 is a cross-sectional perspective view for explaining a basic configuration of pipe heating suitably used in the substrate processing apparatus according to the embodiment;

FIGS. 3A and 3B are cross-sectional perspective views for explaining a basic configuration of other pipe heating suitably used in the substrate processing apparatus according to the embodiment;

FIG. 4 is a block diagram for explaining a fluid supply/discharge mechanism, a heat insulating mechanism, a heating mechanism, and a cooling mechanism suitably used in the substrate processing apparatus according to the embodiment; and

FIG. 5 is a block diagram for explaining a structure of a controller suitably used in the substrate processing apparatus according to the embodiment.

### DETAILED DESCRIPTION

Hereinafter, an embodiment will be described with reference to the drawings. In the following description, however, the same reference numerals will be given to the same constituent elements, and repetitive description may be omitted. Incidentally, in order to make description clearer, a width, a thickness, a shape, and the like of each part in the drawings may be schematically illustrated as compared with those of an actual form, but are only examples, and interpretation of the present invention is not limited thereby.

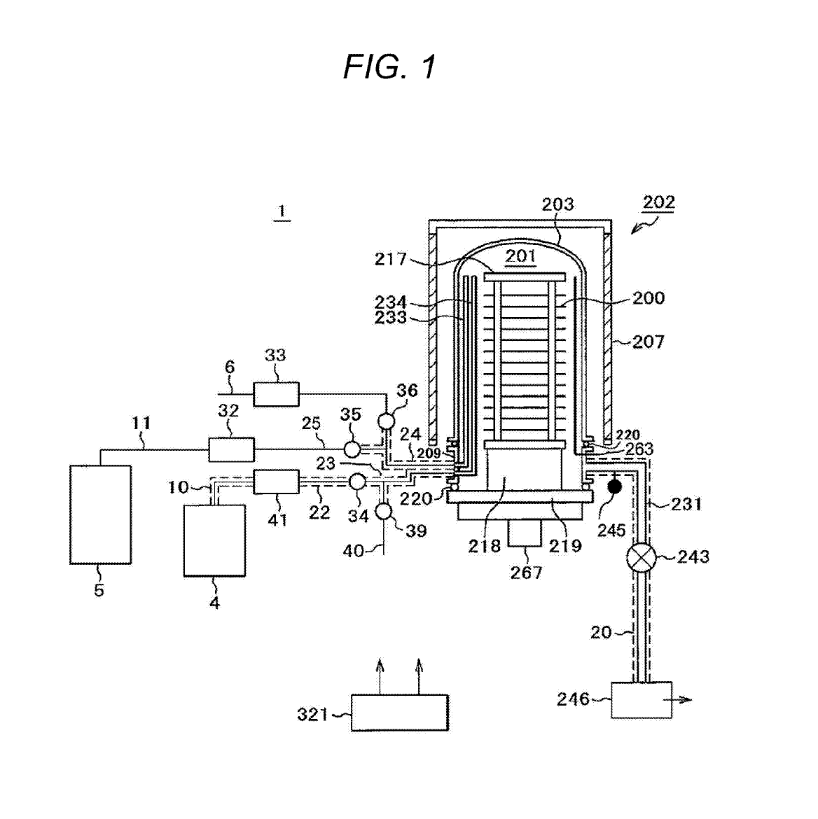

A substrate processing apparatus according to the embodiment will be described with reference to FIG. 1. FIG. 1 illustrates a schematic view when heat insulating pipe 100 described below is used for supply pipe 10, 22, 23, and 24, and exhaust pipe 231 and 20.

As illustrated in FIG. 1, a reaction tube 203 is provided as a process vessel for processing a wafer 200 as a substrate inside a heater 207 as a heating means. A lower end opening of the reaction tube 203 is closed air-tight with a seal cap 219 as a lid body through an O-ring 220 which is an airtight member. At least the heater 207, the reaction tube 203, a manifold 209 as a furnace mouth portion, and the seal cap 219 form a process furnace 202. At least the reaction tube 203, the furnace mouth portion 209, and the seal cap 219 form a process chamber 201. A boat 217 as a substrate holding means is installed in the seal cap 219 through a quartz cap 218 and is inserted into the process chamber 201. A plurality of wafers 200 to be batch-processed is horizontally mounted on the boat 217 in multiple stages. The heater 207 heats the wafers 200 inserted into the process chamber 201 to a predetermined temperature.

A first source gas is supplied into the process chamber 201 from a gas supply unit 4 for the first source gas through the supply pipe 10, a flow rate controller (mass flow controller: MFC) 41 for controlling a flow rate, the supply pipe 22, a valve 34, and the supply pipe 23, and further through a nozzle 234 installed in the process chamber 201. The supply pipe 10, the flow rate controller 41, the supply pipe 22, the valve 34, the supply pipe 23, and the nozzle 234 constitute a first gas supply system. A second source gas is supplied into the process chamber 201 from a gas supply unit 5 for the second source gas through the supply pipe 11, a flow rate controller 32 for controlling a flow rate, the supply pipe 25, a valve 35, and the supply pipe 24, and further through a nozzle 233 installed in the process chamber 201. The supply pipe 11, the flow rate controller 32, the supply pipe 25, the valve 35, the supply pipe 24, and the nozzle 233 constitute a second gas supply system.

Supply pipe 40 for supplying an inert gas is connected to the supply pipe 23 at the upstream side of the valve 34 through a valve 39. Supply pipe 6 for supplying an inert gas is connected to the supply pipe 24 at the upstream side of the valve 35 through a valve 36.

The process chamber 201 is connected to a vacuum pump 246 through an APC valve 243 and the exhaust pipe 20 by the exhaust pipe 231 which is an exhaust pipe for exhausting a gas. The exhaust pipe 231, the APC valve 243, the exhaust pipe 20, and the vacuum pump 246 constitute a gas exhaust system.

The nozzle 234 is installed along a mounting direction of the wafers 200 from a lower part to an upper part of the reaction tube 203. A plurality of gas supply holes for supplying a gas is formed in the nozzle 234. These gas supply holes are opened at an intermediate position between the adjacent wafers 200, and a gas is supplied to a surface of each of the wafers 200. The nozzle 233 is similarly installed along a mounting direction of the wafers 200 at a position around an inner periphery of the reaction tube 203 about 120° from the position of the nozzle 234. A plurality of gas supply holes is also formed in the nozzle 233 similarly. The nozzle 234 supplies the first source gas from the supply pipe 10 and an inert gas from the supply pipe 40 into the process chamber 201. The nozzle 233 supplies the second source gas from the supply pipe 11 and an inert gas from the supply pipe 6 into the process chamber 201. A source gas is alternately supplied from the nozzle 234 and the nozzle 233 into the process chamber 201 to form a film.

In the reaction tube 203, the boat 217 on which the plurality of wafers 200 is mounted in multiple stages at regular intervals is provided, and the boat 217 can be loaded into and unloaded from the reaction tube 203 by a boat elevator (not illustrated). In order to improve processing uniformity, a boat rotation mechanism 267 which is a rotation means for rotating the boat 217 is provided. The boat 217 held on the quartz cap 218 is rotated by rotating the boat rotation mechanism 267.

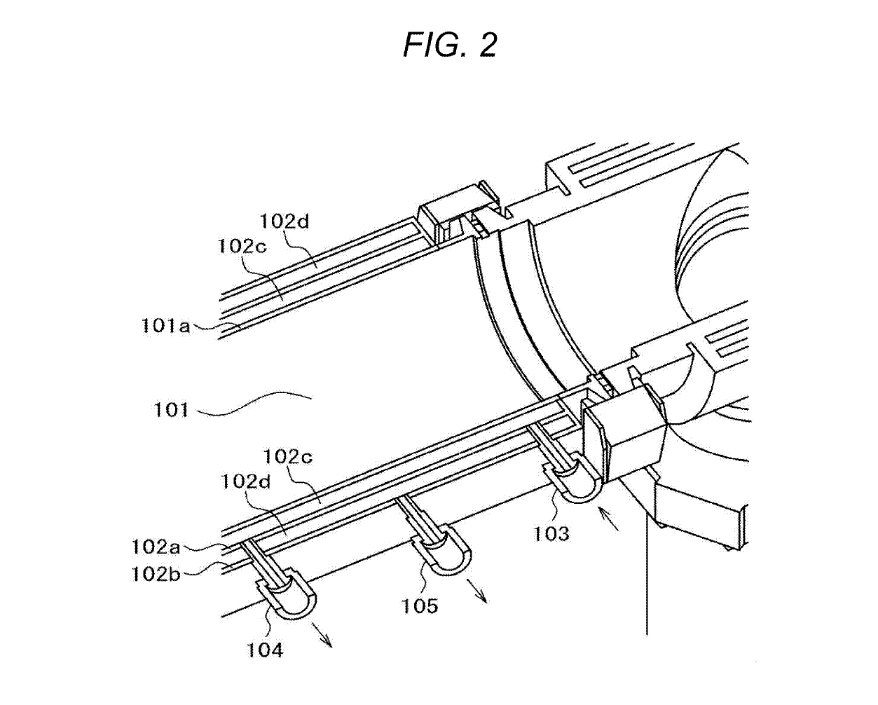

Heat insulating pipe will be described with reference to FIGS. 2 to 4. As illustrated in FIG. 2, the heat insulating pipe 100 includes an inner pipe 101 constituting a flow path (first flow path) of a source gas or an exhaust gas, and an outer pipe 102 provided surrounding the inner pipe 101. The outer pipe 102 includes a first space 102c formed by an inner pipe outer wall 101a and a partition wall 102a as a partition portion, and a second space 102d formed by the partition wall 102a and an outer pipe outer wall 102b. The first space 102c constitutes a belt-shaped flow path (second flow path) through which a fluid medium can flow along (in contact with) the inner pipe outer wall 101a, and the temperature thereof can be raised with a high temperature fluid and the temperature thereof can be lowered with a low temperature fluid. Therefore, the inner pipe 101 is heated or cooled according to the temperature (heat) of a fluid supplied to the second flow path. The second space can be vacuum-exhausted or vacuum-sealed. The heat insulating pipe 100 includes a fluid medium supply pipe 103 for supplying a fluid medium to the first space 102c, a fluid medium discharge pipe 104 for discharging the fluid medium from the first space 102c, and a discharge pipe 105 for vacuum-exhausting the second space 102d.

The first space 102c in FIG. 2 has a belt shape. That is, the first space 102c is provided covering (surrounding) the inner pipe outer wall 101a. With such a heat insulating pipe configuration, a cross-sectional configuration of the heat insulating pipe from the inner pipe outer wall 101a to the outer pipe outer wall 102b is the same as that of the first space 102c, the partition wall 102 a, and the second space 102d. Therefore, ideally, the second space 102d and the inner pipe outer wall 101a are separated from each other by the first space 102c formed by the partition wall 102a. However, in this heat insulating pipe configuration, manufacturing cost is high because the partition wall 102a is also a part of pipe.

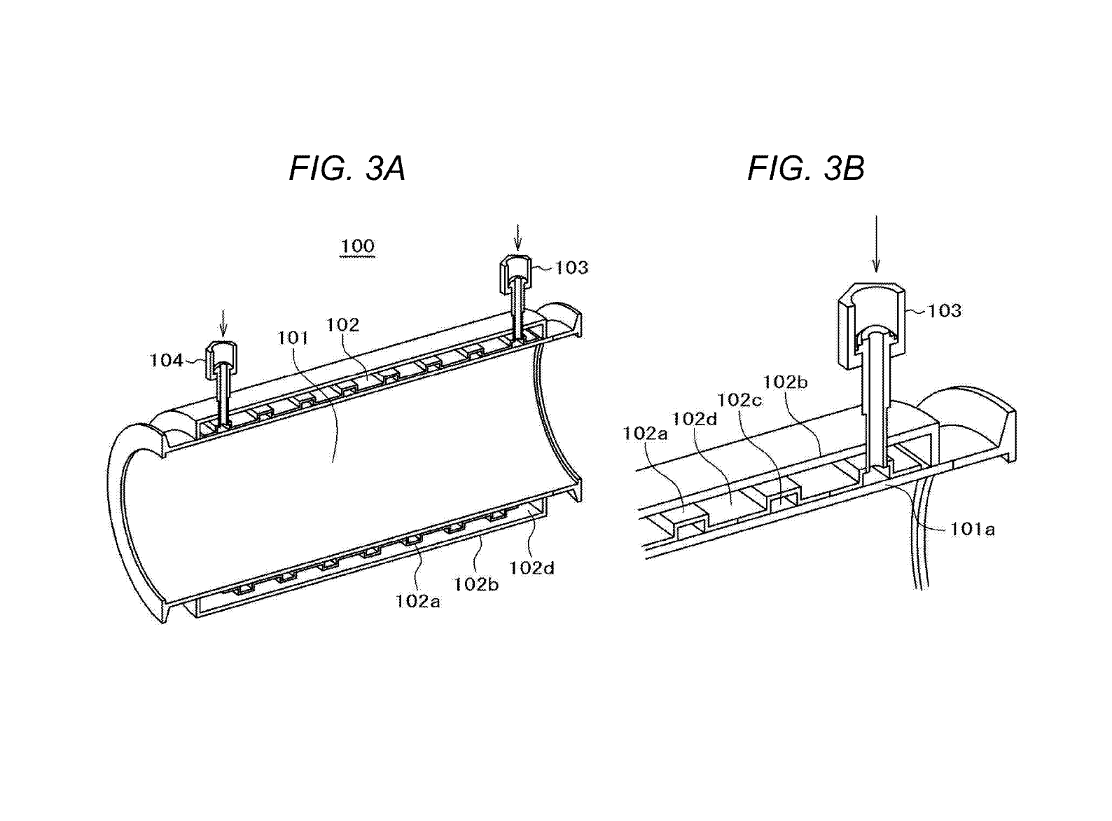

As illustrated in FIGS. 3A and 35, the space 102 may have a spiral shape along the inner pipe outer wall 101a. That is, there may be a part having no space between the inner pipe outer wall 101a and the partition wall 102a. In this case, the first space 102c formed by the partition wall 102a and the inner pipe outer wall 101a constitutes the second flow path, and therefore it can be said that the second flow path has a spiral shape. In this heat insulating pipe configuration, the partition wall 102a is configured as a member (heat insulating member) to form a flow path. Even with such a heat insulating pipe configuration, heat escape from the outer pipe outer wall 102b can be suppressed, and the inner pipe 101 can be heated. Incidentally, a heating unit for heating the inner pipe 101 may be provided in the first space 102c, and the heating unit may be configured so as to be wound around the inner pipe outer wall 101a in a spiral shape. According to this heat insulating pipe configuration, heating of the supply pipe 10, 22, 23, 24 and the exhaust pipe 231 and 20 can be performed more uniformly.

In a case of raising the temperature of the inner pipe 101 of the heat insulating pipe 100, a high temperature fluid is caused to flow in the first space 102c (second flow path) to bring the second space 102d into a vacuum state, and it is thereby possible to suppress convection heat transfer to the outer pipe outer wall 102b and to perform heat insulation. In a case of lowering the temperature of the inner pipe 101 of the heat insulating pipe 100, a low temperature fluid is caused to flow in the first space 102c to transfer the heat of the inner pipe outer wall 101a to the low temperature fluid, and it is possible to accelerate lowering of the temperature. In this case, a fluid (for example, N2) may be supplied to the second space 102d, and the heat of the inner pipe outer wall 101a may be transferred to the fluid of the second space 102d to promote lowering of the temperature.

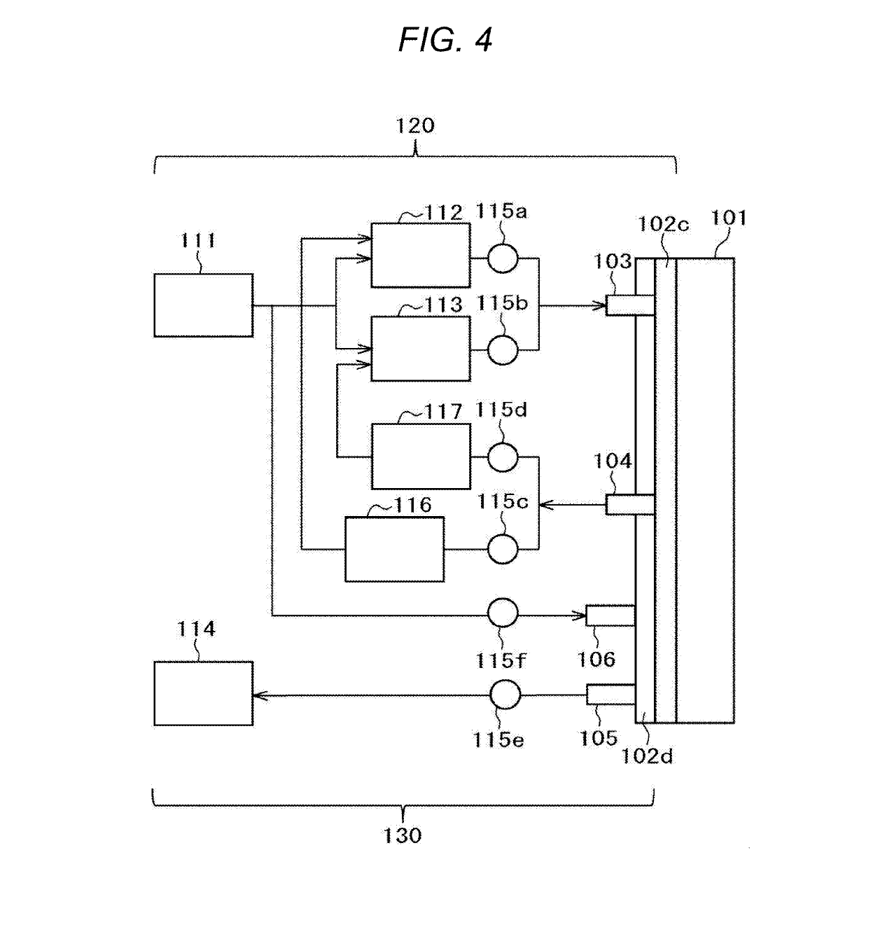

As illustrated in FIG. 4, at the time of substrate processing, a fluid supplied from a fluid supply unit 111 is heated to a predetermined temperature by a fluid heater 112 as a heating mechanism, and is supplied to the first space 102c of the heat insulating pipe 100 through a valve 115a and the fluid medium supply pipe 103. The fluid which has flowed through the first space 102c is returned to the fluid heater 112 through the fluid medium discharge pipe 104, a valve 115c, and a circulation pump 116, is heated again to a predetermined temperature, and is supplied to the first space 102c.

As illustrated in FIG. 4, at the time of maintenance, self cleaning in the process chamber at a low temperature, or the like, a fluid supplied from the fluid supply unit 111 is cooled to a predetermined temperature by a fluid cooler 113 as a cooling mechanism, and is supplied to the first space 102c of the heat insulating pipe 100 through a valve 115b and the fluid medium supply pipe 103. The fluid which has flowed through the first space 102c is returned to the fluid cooler 113 through the fluid medium discharge pipe 104, a valve 115d, and a circulation pump 117, is cooled again to a predetermined temperature, and is supplied to the first space 102c. Incidentally, the predetermined temperature cooled by the fluid cooler 113 is lower than the predetermined temperature heated by the fluid heater 112.

The fluid from the fluid supply unit 111 is supplied to the first space 102c through the fluid heater 112 in an off state, the valve 115a, and the fluid medium supply pipe 103. At this time, the fluid of about room temperature is supplied to the first space 102c. In this way, even with a configuration without the fluid cooler 113, cooling can be performed.

In place of a circulation mechanism for circulating the fluid supplied to the first space 102c to the fluid heater 112 by the circulation pump 116 and to the fluid cooler 113 by the circulation pump 117, the fluid supplied to the first space 102c may be exhausted by an exhaust pump.

The fluid supply unit 111, the fluid heater 112, the fluid cooler 113, the valve 115a, the valve 115b, the fluid medium supply pipe 103, the first space (second flow path) 102c, the fluid medium discharge pipe 104, the valve 115c, and the valve 115d constitute a supply/discharge mechanism 120 for supplying and discharging a fluid.

As illustrated in FIG. 4, at the time of substrate processing, the second space 102d is brought into a vacuum state by a vacuum pump 114 through the discharge pipe 105 and a valve 115e. In place of the vacuum pump 114, the vacuum pump 246 may be used. The second space 102d, the valve 115e, and the vacuum pump 114 constitute a heat insulating mechanism 130 for bringing the space 102d into a vacuum state and thermally insulating the inner pipe 101 from outside air.

Furthermore, as illustrated in FIG. 4, at the time of maintenance and the like, a fluid is supplied to the second space 102d through the valve 115e and a fluid medium supply pipe 106.

A medium supplied to and exhausted from the first space 102c and the second space 102d is only required to be a fluid, and may be a liquid or a gas. A gas which is a medium supplied to the first space 102c and the second space 102d may be any one of inert gases such as N2, He, Ne, Ar, Cr, and Xe gases in addition to the atmosphere.

For example, the inner pipe 101, the outer pipe 102, and the partition wall 102a are formed of a metal member such as stainless steel, an aluminum alloy, or a nickel alloy, or a metal member coated with a coating for corrosion resistance.

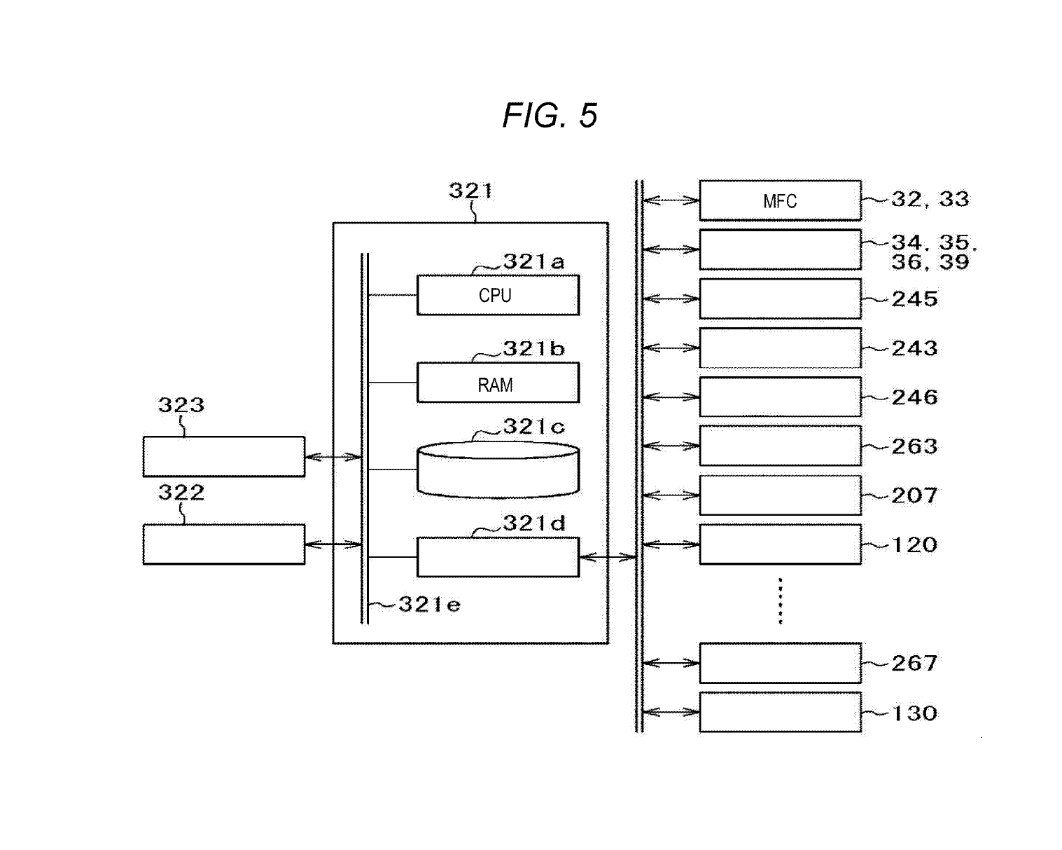

A controller will be described with reference to FIG. 5.A controller 321 which is a control unit (control means) is configured as a computer including a central processing unit (CPU) 321a, a random access memory (RAM) 321b, a memory device 321c, and an I/O port 321d. The RAM 321b, the memory device 321c, and the I/O port 321d are configured so as to be able to exchange data with the CPU 321a through an internal bus 321e. An input/output device 322 configured, for example, as a touch panel is connected to the controller 321.

The memory device 321c is configured, for example, by a flash memory and a hard disk drive (HDD). In the memory device 321c, a control program for controlling an operation of a substrate processing apparatus, a process recipe in which procedures and conditions of substrate processing described below are written, and the like are readably stored. Incidentally, the process recipes are combined with each other such that a predetermined result can be obtained by causing the controller 321 to execute each procedure in the substrate processing step described below. The RAM 321b is configured as a memory area (work area) in which a program, data, or the like read by the CPU 321a is temporarily stored.

The I/O port 321d is connected to the flow rate controllers 32 and 33, the valves 34, 35, 36, and 39, a pressure sensor 245, the APC valve 243, the vacuum pump 246, the heater 207, a temperature sensor 263, the rotation mechanism 267, the supply/discharge mechanism 120, the heat insulating mechanism 130, and the like.

The CPU 321a is configured to read a control program from the memory device 321c and execute the program, and to read a process recipe from the memory device 321c in accordance with input of an operation command from the input/output device 322 or the like. The CPU 321a is configured to, according to the content of the process recipe thus read, control flow rate adjusting operations of various gases by the flow rate controllers 32, 33, and 41, opening/closing operations of the valves 34, 35, 36, and 39, an opening/closing operation of the APC valve 243, a pressure adjusting operation by the APC valve 243 based on the pressure sensor 245, a temperature adjusting operation of the heater 207 based on the temperature sensor 263, a start/stop operation of the vacuum pump 246, operations of rotating the boat 217 with the rotation mechanism 267 and adjusting a rotational speed of the boat 217, an operation of adjusting temperatures of the supply pipe 10, 22, 23, and 24, and the exhaust pipe 231 and 20 by the supply/discharge mechanism 120 and the heat insulating mechanism 130, and the like.

Incidentally, the controller 321 can be configured by installing the above program stored in an external memory device (for example, a semiconductor memory such as a USB memory or a memory card) 323 in a computer. The memory device 321c or the external memory device 323 is configured as a computer-readable recording medium. Hereinafter, these are also collectively and simply referred to as a recording medium. Here, the term “recording medium” may include only the memory device 321c itself, may include only the external memory device 323 itself, or may include both of these. Incidentally, provision of a program to a computer may be performed using a communication means such as the Internet or a dedicated line without using the external memory device 323.

Next, a sequence example of processing for forming a film on a substrate (hereinafter, also referred to as film formation processing) will be described as one step of a process for manufacturing a semiconductor device (device) using a substrate processing apparatus 1. Here, an example in which a film is formed on each of the wafers 200 as a substrate by alternately supplying a first processing gas (source gas) and a second processing gas (reaction gas) to the wafers 200 will be described.

Hereinafter, an example in which a silicon nitride film (Si3N4 film, hereinafter also referred to as SiN film) is formed on each of the wafers 200 using a hexachlorodisilane (Si2Cl6, abbreviation: HCDS) gas as a source gas and using an ammonia (NH3) gas as a reaction gas will be described. Incidentally, in the following description, an operation of each part constituting the substrate processing apparatus 1 is controlled by the controller 321.

In film formation processing in the present embodiment, a SiN film is formed on each of the wafers 200 by performing a predetermined number of times (one or more times) of cycles of non-simultaneously performing a step of supplying an HCDS gas to the wafers 200 in the process chamber 201, a step of removing the HCDS gas (residual gas) from the interior of the process chamber 201, a step of supplying an NH3 gas to the wafers 200 in the process chamber 201, and a step of removing the NH3 gas (residual gas) from the interior of the process chamber 201.

Here, the term “substrate” is synonymous with the term “wafer”.

When the plurality of wafers 200 is loaded into the boat 217, the boat 217 is carried into the process chamber 201 by a boat elevator (not illustrated). At this time, the seal cap 219 gets closed (sealed) airtight at a lower end of the reaction tube 203 through the O-ring 220.

(Pressure Adjustment and Temperature Adjustment)

The vacuum pump 246 performs vacuum exhaust (decompression exhaust) such that the interior of the process chamber 201, that is, a space where the wafers 200 exist, has a predetermined pressure (degree of vacuum). At this time, the pressure inside the process chamber 201 is measured by the pressure sensor 245, and the APC valve 243 is feedback-controlled based on the measured pressure information. The vacuum pump 246 maintains a state of being normally operated at least until processing on the wafers 200 is completed.

The wafers 200 in the process chamber 201 are heated by the heater 207 to a predetermined temperature. At this time, the degree of energization to the heater 207 is feedback-controlled based on temperature information detected by the temperature sensor 263 such that the process chamber 201 has a predetermined temperature distribution. Heating in the process chamber 201 by the heater 207 is continuously performed at least until processing on the wafers 200 is completed.

Rotation of the boat 217 and the wafers 200 by the rotation mechanism 267 is started. The boat 217 is rotated by the rotation mechanism 267, and the wafers 200 are thereby rotated. The rotation of the boat 217 and the wafers 200 by the rotation mechanism 267 is continuously performed at least until processing on the wafers 200 is completed.

When the temperature inside the process chamber 201 becomes stable at a preset processing temperature, the following two steps, that is, steps 1 and 2 are sequentially executed.

In Step 1, an HCDS gas is supplied to the wafers 200 in the process chamber 201. The valve 34 is opened, and the HCDS gas is caused to flow from the gas supply unit 4 for the first source gas into the supply pipe 23 through the supply pipe 10, the MFC 41, and the supply pipe 22. The flow rate of the HCDS gas is adjusted by the MFC 41, is supplied to the process chamber 201 through the nozzle 234, and is exhausted from the exhaust pipe 231 and 20. At this time, the HCDS gas is supplied to the wafers 200. At this time, the valve 39 is opened simultaneously, and an N2 gas is caused to flow into the supply pipe 23 through the supply pipe 40. The N2 gas is supplied into the process chamber 201 together with the HCDS gas and is exhausted from the exhaust pipe 231. At this time, the supply pipe 10, 22, and 23 and the exhaust pipe 231 and 20 are heated. By supplying the HCDS gas to the wafers 200, a Si-containing layer having a thickness of, for example, less than one atomic layer to several atomic layers is formed as a first layer on the outermost surface of the wafers 200.

After the first layer is formed, Step 2 is performed whereby the valve 34 is closed and supply of HCDS gas is stopped. At this time, with the APC valve 243 open, the interior of the process chamber 201 is vacuum-exhausted by the vacuum pump 246, and the HCDS gas which remains in the process chamber 201, is unreacted, or has contributed to formation of the first layer is discharged from the interior of the process chamber 201. At this time, the supply of the N2 gas into the process chamber 201 is maintained with the valve 39 open. The N2 gas acts as a purge gas, and an effect of discharging the gas remaining in the process chamber 201 from the interior of the process chamber 201 can be thereby enhanced.

After step 1 is completed, Step 2 is an NH3 gas is supplied to the wafers 200 in the process chamber 201, that is, to the first layer formed on the wafers 200. The NH3 gas is activated by heat and supplied to the wafers 200.

In this step, opening/closing control of the valves 35 and 36 is performed in a similar procedure to the opening/closing control of the valves 34 and 39 in step 1. The NH3 gas is supplied from the gas supply unit 5 for the second source gas through the supply pipe 11, and the flow rate thereof is adjusted by an MFC 32. The NH3 gas is supplied into the process chamber 201 through the supply pipe 25 and 24 and the nozzle 233, and is exhausted from the exhaust pipe 231 and 20. At this time, the NH3 gas is supplied to the wafers 200. At this time, the supply pipe 24 and the exhaust pipe 231 and 20 are heated. The NH3 gas supplied to the wafers 200 reacts with at least a part of the first layer formed on the wafers 200, that is, with the Si-containing layer in step 1. The first layer is thereby thermally nitrided with non-plasma and is changed (modified) to a second layer, that is, to a silicon nitride layer (SiN layer).

After the second layer is formed, the valve 35 is closed and supply of the NH3 gas is stopped. Then, by a similar process procedure to step 1, the NH3 gas which remains in the process chamber 201, is unreacted, or has contributed to formation of the second layer, or reaction by-products are discharged from the interior of the process chamber 201. At this time, similarly to step 1, it is not necessary to completely discharge the gas or the like remaining in the process chamber 201.

By performing a predetermined number of times (n times) of cycles of non-simultaneously, that is, non-synchronously, performing the above two steps, a SiN film having a predetermined film thickness can be formed on each of the wafers 200. Incidentally, preferably, the thickness of the second layer formed during performance of the above one cycle is smaller than the predetermined film thickness, and a plurality of times of the above cycles is performed repeatedly until the film thickness of the SiN film formed by stacking the second layer becomes the predetermined film thickness.

After the film formation processing is completed, the valves 36 and 39 are opened, and the N2 gas is supplied into the process chamber 201 from the supply pipe 24 and 23 through the supply pipe 6, 26, and 40, and is exhausted from the exhaust pipe 231 and 20. The N2 gas acts as a purge gas. As a result, the interior of the process chamber 201 is purged, and the gas remaining in the process chamber 201 and reaction by-products are removed from the interior of the process chamber 201 (purge). Thereafter, the atmosphere in the process chamber 201 is replaced with an inert gas (inert gas replacement), and the pressure in the process chamber 201 is returned to a normal pressure, is returned to atmospheric pressure.

Boat unloading and wafer discharge one then performed where by the seal cap 219 is lowered by a boat elevator and a lower end of the reaction tube 203 is opened. The processed wafers 200 are carried out from the lower end of the reaction tube 203 to an outside of the reaction tube 203 while being supported by the boat 217. The processed wafers 200 are taken out from the boat 217.

According to the present embodiment, at least one or more of the following effects (a) to (e) are exhibited.

(a) By causing a heating fluid medium to flow through a flow path formed along an inner pipe outer wall, a cold spot caused by temperature unevenness can be suppressed, and therefore thermal evenness can be improved.

(b) By suppressing a cold spot, adhesion of by-products such as NH4Cl to an interior of pipe (inner pipe inner wall) can be suppressed, and a maintenance cycle can be prolonged.

(c) By causing a cooling fluid medium to flow through a flow path, a temperature lowering rate of a pipe temperature can be improved, processing and work at a low temperature can be promptly performed, and a throughput of an apparatus can be shortened. Processing at a low temperature is, for example, self cleaning in a process chamber using a halogen-based gas which increases a corrosion risk of pipe when a gas flows at a high temperature.

(d) Due to vacuum insulation, heat radiation to an outside of pipe can be suppressed, a temperature inside a box housing the pipe can be prevented from becoming a high temperature, and constraints on placement of temperature constrained parts can be eliminated.

(e) Due to vacuum insulation, heat radiation to an outside of pipe can be suppressed, therefore a heat insulating material can be eliminated, or a local cooling means performed by providing a fan, a water cooling plate, or the like can be eliminated.

Embodiments of the present teachings have been specifically described above. However, the teaching is not limited to the above-described embodiment, and various modifications can be made within a range not departing from the gist thereof.

For example, in one embodiment, the heat insulating pipe is applied to both the supply pipe and the exhaust pipe, but may be applied to only either the supply pipe or the exhaust pipe.

In another embodiment, a nitride film (SiN or the like) has been exemplified, but the film type is not particularly limited. For example, the embodiment can be applied to various film types such as an oxide film (SiO or the like) and a metal oxide film.

Furthermore, in the above-described embodiment, a case where a film is deposited on a wafer has been exemplified. However, the present invention is not limited to such a form. For example, the present invention can also be suitably applied to cases where oxidizing processing, diffusion processing, annealing processing, etching processing, or the like is performed on a wafer, a film formed on a wafer, or the like.

In addition, in the embodiment, the vertical substrate processing apparatus of batch processing has been described, but the present invention is not limited thereto, but can be applied to a substrate processing apparatus for sheet processing.

Furthermore, the present invention is not limited to a semiconductor manufacturing apparatus for processing a semiconductor wafer, such as the substrate processing apparatus according to the present embodiment, but can also be applied to a liquid crystal display (LCD) manufacturing apparatus for processing a glass substrate.

What is claimed is:

1. A substrate processing apparatus, comprising:
a process chamber for processing a substrate; a gas supply system including supply pipe for supplying a source gas into the process chamber; and an exhaust system including exhaust pipe for discharging an exhaust gas containing the source gas from the process chamber, wherein
at least one of the supply pipe and the exhaust pipe includes: an inner pipe constituting a first flow path of the source gas or the exhaust gas; a member provided outside the inner pipe and constituting a second flow path between the member and an outer wall of the inner pipe; and an outer pipe provided surrounding the inner pipe in order to provide a space between the outer pipe and an outside of the member.

2. The substrate processing apparatus according to claim 1, further comprising: a supply/discharge mechanism for supplying and discharging a fluid through the second flow path; a heat insulating mechanism for bringing the space into a vacuum state and thermally insulating the inner pipe from outside air; and a control unit for controlling the heat insulating mechanism and the supply/discharge mechanism such that the inner pipe is heated and cooled to a predetermined temperature by controlling supply/discharge of the fluid flowing in the second flow path and an atmosphere of the space.

3. The substrate processing apparatus according to claim 1, wherein the space is in contact with at least a part of the outer wall of the inner pipe, and the second flow path is provided in a spiral shape along the outer wall of the inner pipe.

4. A heat insulating pipe structure comprising: an inner pipe constituting a flow path of a source gas or an exhaust gas; a member provided outside the inner pipe and constituting a second flow path between the member and an outer wall of the inner pipe; and an outer pipe provided surrounding the inner pipe in order to provide a space between the outer pipe and the member.

5. A heat insulating pipe structure comprising: an inner pipe constituting a flow path of a source gas or an exhaust gas; and an outer pipe provided surrounding the inner pipe and having a space inside, wherein
the outer pipe is configured to have a first space provided covering the inner pipe and including a second flow path for circulating a fluid for heating and cooling the inner pipe, and a second space provided covering the first space and capable of being vacuum-exhausted or vacuum-sealed, isolated from each other.

6. The substrate processing apparatus according to claim 1, wherein the outer pipe is configured to have a first space including a second flow path for circulating a fluid for heating and cooling the inner pipe and a second space capable of being vacuum-exhausted or vacuum-sealed.

7. The substrate processing apparatus according to claim 2, further comprising a heating mechanism for heating the fluid or a cooling mechanism for cooling the fluid,
wherein the fluid is configured to be heated or cooled to a predetermined temperature in advance.

8. The substrate processing apparatus according to claim 7, wherein the inner pipe is configured to be heated and cooled according to a temperature of a fluid supplied to the second flow path.

9. The substrate processing apparatus according to claim 2, wherein the control unit is configured to supply the fluid from a vacuum state to the second space, transmit heat of a wall of the inner pipe to the fluid of the second space, and promote lowering of the temperature when lowering a temperature of the inner pipe.

10. The substrate processing apparatus according to claim 2, wherein the control unit is configured to adjust each of a temperature of the pipe at the time of substrate processing and a temperature of the pipe at the time of maintenance to a predetermined temperature.

11. The substrate processing apparatus according to claim 2, wherein the fluid is air or any one gas selected from the group consisting of N2, He, Ne, Ar, Cr, and Xe.

12. The heat insulating pipe structure according to claim 5, configured such that the first space is in contact with at least a part of the outer wall of the inner pipe and the flow path included in the first space is provided in a spiral shape along the outer wall of the inner pipe.

13. The heat insulating pipe structure according to claim 5, wherein the outer pipe has a sealed structure capable of vacuum-exhausting and vacuum-sealing the second space.

14. The heat insulating pipe structure according to claim 5, further comprising a heating unit for heating the inner pipe in the first space, wherein
the heating unit is configured to be wound around the outer wall of the inner pipe in a spiral shape.
